(19) United States
(12) Patent Application Publication
(10) Pub. No.: US 2019/0123080 A1
(43) Pub. Date: Apr. 25, 2019

(54) SENSOR CIRCUITS FOR X-RAY IMAGERS

(71) Applicant: The Regents of the University of Michigan, Ann Arbor, MI (US)

(72) Inventors: Jerzy Kanicki, Ann Arbor, MI (US); Mao-Hsun Cheng, Ann Arbor, MI (US); Chumin Zhao, Townson, MD (US); Aunnasha Sengupta, Ann Arbor, MI (US)

(21) Appl. No.: 16/165,816

(22) Filed: Oct. 19, 2018

Related U.S. Application Data
(60) Provisional application No. 62/574,505, filed on Oct. 19, 2017.

(51) Int. Cl. H01L 27/146; H01L 27/30; H01L 27/28

(52) U.S. Cl. CPC H01L 27/14616; H01L 27/308; H01L 27/307; H01L 27/286; H01L 27/14663; H01L 27/1225; H01L 27/14623; H01L 27/14692; H01L 27/14603; H01L 27/1461; H01L 27/14676

(57) ABSTRACT

An active pixel sensor includes thin-film transistors (TFTs) fabricated on a glass substrate, the TFTs include a gate electrode patterned on the glass substrate; a gate insulator layer disposed over the gate electrode; an amorphous indium-tin-zinc-oxide (a-ITZO) active semi-conductor layer disposed on the gate insulator layer and patterned over the gate electrode; and a source electrode and a drain electrode patterned from a metal layer deposited over the a-ITZO layer.

### CROSS-REFERENCE TO RELATED APPLICATION

This application claims the benefit of U.S. Provisional Application No. 62/574,505 filed Oct. 19, 2018, the entire contents of which are hereby incorporated by reference.

### TECHNICAL FIELD

The present disclosure relates generally to active pixel sensor (APS) circuits for indirect and direct X-ray imagers, and in particular, to high-performance APS circuits for next-generation large area, low noise, high resolution X-ray imagers.

### BACKGROUND

Ideally, to achieve the best imaging performance in terms of higher detective quantum efficiency (DQE), an imaging system should be quantum limited, which means that the only source of noise is the x-ray quantum noise. However, this is seldom the case, as the conventional amorphous silicon (a-Si) thin film transistor (TFT)-based passive pixel sensor (PPS) backplane of x-ray imagers are a source of the additive electronic noise, which becomes a significant component of the total noise of the imaging system. While this high electronic noise can be tolerated for high exposure applications, such as mammography and general radiography, for low-dose imaging modalities, like digital breast tomosynthesis (DBT), it is crucial to reduce the electronic noise component as much as possible.

One approach to improve the noise performance (noise power spectrum (NPS)) is by employing an active pixel sensor (APS) instead of the currently used PPS backplane.

### SUMMARY

According to one aspect of the invention, there is provided an active pixel sensor that includes thin-film transistors (TFTs) fabricated on a glass substrate. The TFTs include a gate electrode patterned on the glass substrate; a gate insulator layer disposed over the gate electrode; an amorphous indium-tin-zinc-oxide (a-ITZO) active semi-conductor layer disposed on the gate insulator layer and patterned over the gate electrode; and a source electrode and a drain electrode patterned from a metal layer deposited over the a-ITZO layer.

According to another aspect of the invention, there is provided an active pixel sensor imaging array for large-area x-ray imagers. The array includes a plurality of active pixel sensors arranged in rows and columns, wherein each of the plurality of active pixel sensors are coupled to an external readout circuit and includes a reset thin-film transistors (TFT), an amplifier TFT, and a readout TFT fabricated on a glass substrate. Each of the TFTs include a gate electrode patterned on the glass substrate; a gate insulator layer disposed over the gate electrode; an amorphous indium-tin-zinc-oxide (a-ITZO) active semi-conductor layer disposed on the gate insulator layer and patterned over the gate electrode; and a source electrode and a drain electrode patterned from a metal layer deposited over the a-ITZO layer; a photodetector fabricated over each of the active pixel sensors to form a vertically-stacked imaging pixel.

According to another aspect of the invention, there is provided an x-ray imaging device that includes an active pixel sensor imaging array having a plurality of active pixel sensors arranged in rows and columns, each of the plurality of active pixel sensors include thin-film transistors (TFTs) fabricated on a glass substrate. The TFTs include a gate electrode patterned on the glass substrate; a gate insulator layer disposed over the gate electrode; an amorphous indium-tin-zinc-oxide (a-ITZO) active semi-conductor layer disposed on the gate insulator layer and patterned over the gate electrode; and a source electrode and a drain electrode patterned from a metal layer deposited over the a-ITZO layer; a photodetector fabricated over the over each active pixel sensor forming vertically-stacked imaging pixel; and a readout circuit coupled to each of the plurality of active pixel sensors.

### BRIEF DESCRIPTION OF THE DRAWINGS

One or more embodiments of the invention will hereinafter be described in conjunction with the appended drawings, wherein like designations denote like elements, and wherein:

FIGS. 1A-C illustrate cross-sectional views of an a-ITZO TFT, an organic photodiode, and an a-Si photodiode in accordance with an embodiment of the invention;

FIG. 2 illustrates an exemplary CsI:Tl scintillator/a-Si PD structure in accordance with an embodiment of the invention;

FIGS. 3A-C illustrate readout circuits for a MOS-based readout circuit, a charge integrator, and a trans-impedance amplifier (TIA), respectively, in accordance with an embodiment of the invention;

FIGS. 4A-B illustrate pixel sensor schematics and corresponding timing diagrams for a SF V-APS in accordance with an embodiment of the invention;

FIGS. 5A-B illustrate pixel sensor schematics and corresponding timing diagrams for a CS V-APS in accordance with an embodiment of the invention;

FIGS. 6A-B illustrate pixel sensor schematics and corresponding timing diagrams for a TA SO C-APS in accordance with an embodiment of the invention;

FIGS. 7A-B illustrate pixel sensor schematics and corresponding timing diagrams for a TA DO C-APS in accordance with an embodiment of the invention;

FIGS. 8A-B illustrate pixel sensor schematics and corresponding timing diagrams for a an a-ITZO APS and a TIA readout circuit in accordance with an embodiment of the invention;

FIGS. 9A-B illustrate a pixel pitch layout for an a-ITZO TFT C-APS and a cross-section view of the a-ITZO TFT C-APS layer, respectively, in accordance with an embodiment of the invention;

FIGS. 10A-B illustrate a pixel pitch layout for the a-ITZO TFT V-APS and a cross-section view of the a-ITZO TFT V-APS layer, respectively, in accordance with an embodiment of the invention;

FIGS. 11A-J illustrate cross-sectional views of the fabrication steps for the a-ITZO TFT C-APS according to the pixel layout shown in FIG. 9A in accordance with an embodiment of the invention;

FIG. 12 illustrates a cross-sectional view (B to B′) of the data line, V_{RS} and V_{M} pads according to the pixel layout shown in FIG. 9A in accordance with an embodiment of the invention;

FIG. 13 illustrates a cross-sectional schematic of TRD and the data line series resistance (RDATA) and parasitic capacitances (CDATA) for a TFT in accordance with an embodiment of the invention;

FIG. 14 illustrates a cross-section view of a DO a-ITZO TFT and the a-Si:H photodiode fabrication with no additional layer for GND bus line in accordance with an embodiment of the invention;

FIG. 15 illustrates a cross-section view of a DO a-ITZO TFT and the a-Si:H photodiode fabrication with an additional layer for GND bus line in accordance with an embodiment of the invention;

FIGS. 16A-F illustrate cross-sectional views of various configurations for an a-ITZO TFT C-APS in accordance with an embodiment of the invention;

FIGS. 17A-D depict schematics of equivalent circuits and cross-sectional views for a-Se TFT C-APS imager in accordance with an embodiment of the invention.

### DESCRIPTION OF THE ILLUSTRATED EMBODIMENTS

Thin film transistor (TFT)-based active pixel sensors (APS) for large-area, low noise, high resolution X-ray imagers are disclosed. Various TFT APS configurations disclosed herein include a source output (SO) current-mode APS (C-APS), a drain output (DO) current-mode C-APS (C-APS), a source follower (SF) voltage-mode APS (V-APS), and a common source (CS) V-APS. The disclosed TFT APSs use metal oxides for the active semiconductor layer. More specifically, an amorphous indium-tin-zinc-oxide (In—Sn—Zn—O) is used as it boasts of higher field effect mobilities (μ_{eff}>30 cm²/V s), lower off-current (I_{OFF}, <10⁻¹⁴ A) and a steep subthreshold slope (SS<200 mV/decade), and a low OFF-current (I_{OFF}<10⁻¹⁴ A), which are suitable for applications such as X-ray imagers. The active semiconductor layer may also be an amorphous indium-gallium-zinc-oxide (In—Ga—Zn—O).

The disclosed TFT APSs further include a top-illuminated photodetector such as, for example, an organic photodiode (OPD), an amorphous silicon p+-i-n+ photodiode (a-Si p+-i-n+ PD), a photoconductive material such as amorphous selenium, mercury iodide, or an organometallic halide perovskite. The photodiode structures may be configured as top-anode (TA) or top-cathode (TC). Using a stack-up structure the disclosed TFT APS has a 50-micrometer pixel pitch.

An x-ray imager employing an imaging array of the disclosed TFT APSs includes readout circuitry for generating images, including, for example, a MOS-based readout circuit, a charge integrator, and a trans-impedance amplifier.

### Device Fabrications

### A. Amorphous Indium-Tin-Zinc-Oxide Thin-Film Transistor

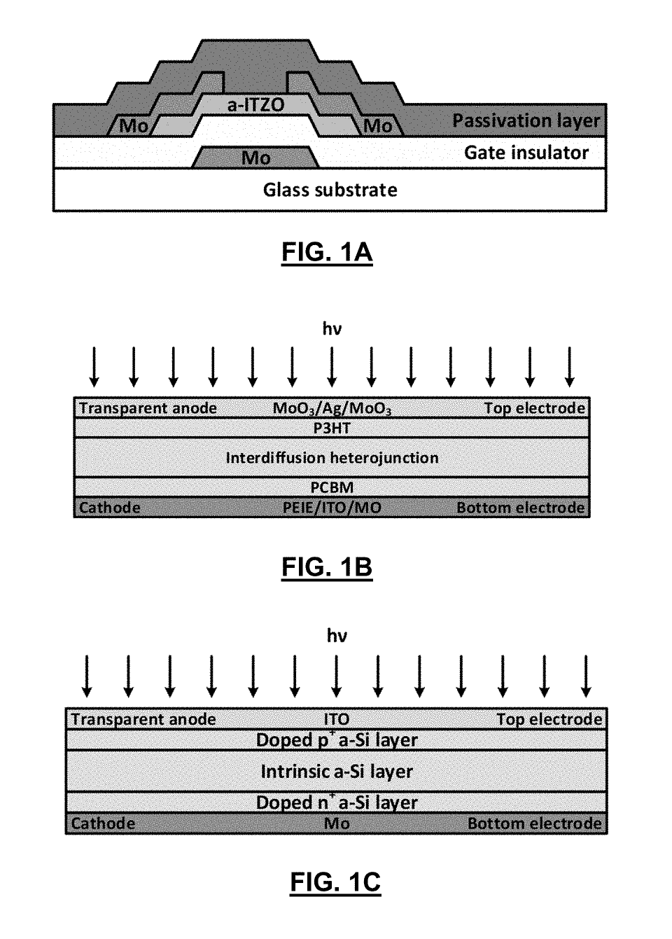

The fabrication process of the back-channel-etched a-ITZO TFT includes first forming a gate electrode (Mo) on a glass substrate. After patterning the gate electrode, a 470-nm-thick amorphous silicon dioxide (SiOₓ) as a gate insulator is deposited using plasma-enhanced chemical vapor deposition (PECVD). Next, a 30-nm-thick a-ITZO film is deposited by DC sputtering with an O₂ flow ratio of 5%, subsequently patterned by a wet etching process, and then annealed at 300° C. Afterward, the source and drain electrodes (Mo) are deposited by sputtering and patterned by phosphoric acid, acetic acid, and nitric acid etchant. A second annealing process at 200° C. is applied in ambient air. Finally, an organic or inorganic film acting as a passivation layer is deposited over the a-ITZO TFT. FIG. 1 (a) shows a cross-sectional view of the a-ITZO TFT.

### B. Photodiodes (PDs)—Indirect Imaging

Organic Photodiode (OPD): The OPD fabrication process is briefly summarized. A combination of Molydenum (Mo) for the source and drain electrodes and ITO is used as the bottom cathode electrode. A synthesized polyethylenimine ethoxylated (PEIE) solution is spin-coated on the top of ITO and annealed at 100° C. to form a 10-nm-thick layer. Afterward, a 90-nm-thick phenyl C61-butyric acid methyl ester (PCBM) layer (electron acceptor) is deposited by spin coating. Subsequently, a 90-nm-thick poly (3-hexylthiophene) (P3HT) (electron donor) is transferred by a double transfer stamping method from a high-surface-energy polydimethylsiloxane stamp onto the PCBM/PEIE/ITO/Mo structure. The P3HT/PCBM/PEIE/ITO/Mo structure is next annealed at 110° C. to generate an inter-diffusion layer between P3HT and PCBM (P3HT/inter-diffusion heterojunction/PCBM/PEIE/ITO/Mo). Finally, a 5-nm-thick MoO₃, a 10-nm-thick Ag, and a 35-nm-thick MoO₃ are sequentially deposited on the top to form a transparent anode electrode. The OPD is illuminated through the top transparent anode. FIG. 1(b) shows the cross-sectional view of the OPD.

Amorphous Silicon p+-i-n+ Photodiode: The fabrication process of the a-Si p+-i-n+ PD is briefly summarized. Mo is used for the source and drain electrodes as the bottom cathode electrode. Using PECVD, a 50-nm-thick heavily P-doped (n+) layer, a 1-μm-thick undoped/intrinsic a-Si layer, and a 50-nm-thick heavily B-doped (p+) layer are sequentially deposited. Next, ITO, a transparent anode electrode, is deposited on the top of the p+ layer. Then, the a-Si p+-i-n+ PD is annealed at 150° C. to suppress the excess current coming from extrinsic defect generation. The a-Si p+-i-n+ PD is top-illuminated through the transparent ITO anode. This PD structure is adopted to realize a low dark current under reverse bias and high quantum efficiency (Q.E.). FIG. 1(c) shows the cross-sectional view of the a-Si PD.

### Signal Generation and Transfer in Active Pixel Sensor

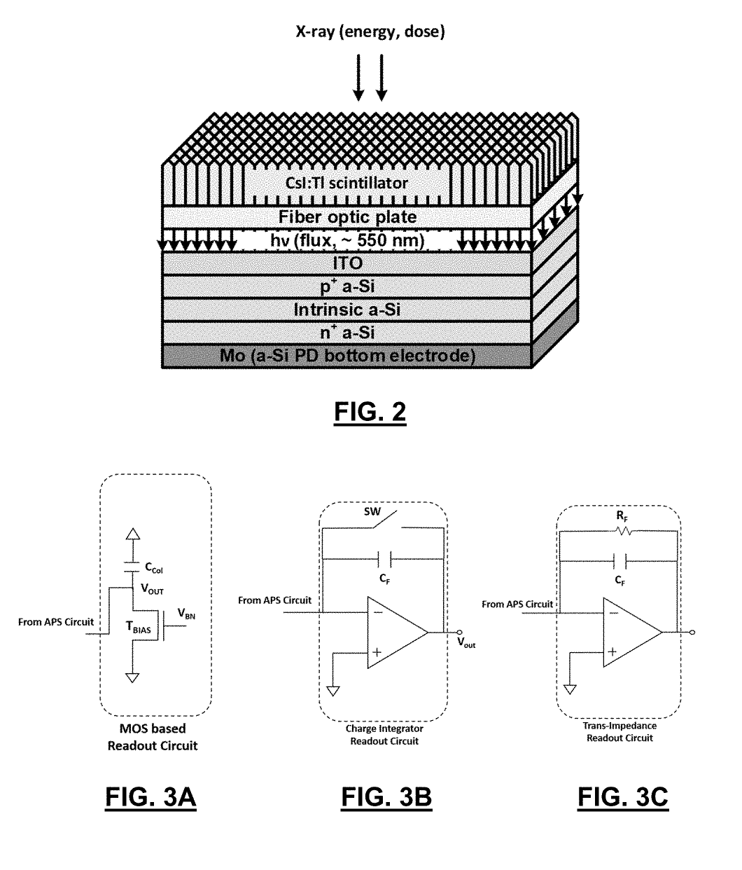

An example of a CsI:Tl scintillator/a-Si PD structure is shown in FIG. 2. In the a-Si PD, the ITO/B-doped p⁺ a-Si and Mo/P-doped n⁺ a-Si layers are considered as an anode and a cathode, respectively. First, x-rays projected on the scintillator will generate visible light/photon emission whose quantity is defined by the flux and energy of x-rays. The fiber optic plate (FOP) is used to convey the photons emitted from the scintillator to the a-Si PD. Next, the a-Si PD, subjected to reverse-biased condition, will absorb the photons, and produce electron-hole pairs, resulting in carriers. Electrons are attracted by the high-voltage a-Si PD cathode; holes move toward to the low-voltage a-Si PD anode. The movement of holes and electrons forms a-Si PD photocurrents, flowing from the a-Si PD cathode to anode. The density of the photo-generated carriers is linearly proportional to the density (flux) of the photons. Subsequently, PPS and/or APS act as mediators to convert different levels of photo-induced signals/photocurrents into different levels of electrical signals (currents and voltages). The a-Si PD can have TA or TC structure. In both configurations V_{RD} is used to activate readout TFT (T_{RD}), allowing the transfer of the photo-induced signals from a pixel to the external readout circuit. V_{PD} and V_{REF} of the readout circuit are voltages used to reversely bias the a-Si PD. In TA structure, V_{PD} and V_{REF} are set at a low voltage and a high voltage, respectively; the cathode of the a-Si PD is connected to the TFT (T_{RD}), and the anode is illuminated through a transparent indium-tin oxide (ITO)/p⁺ a-Si electrode. In TC configuration, V_{PD} and V_{REF} are set at a high voltage and a low voltage, respectively; the connection of the a-Si PD is reversed and the diode is illuminated through a transparent ITO layer/n⁺ a-Si electrode.

### Readout Circuits

As shown in FIGS. 3A-C, readout circuits for the disclosed TFT APS include a MOS-based readout circuit, a charge integrator, and a trans-impedance amplifier (TIA). The MOS-based readout circuit shown in FIG. 3A converts the voltage at its input node into the corresponding output voltage. The MOS-based readout circuit has a simple and compact structure as compared to the charge integrator and trans-impedance amplifier, but doesn't provide any signal amplification.

The charge integrator shown in FIG. 3B consists of an operational amplifier op-amp, a feedback capacitor (C_{F}), and an external reset switch (SW). Another possible readout mechanism is the trans-impedance amplifier shown in FIG. 3C, which has a circuit is similar to that of the charge integrator but consists of a feedback resistance (R_{F}) instead of the switch. In essence, both the readout mechanisms can be considered to convert current into output voltages.

There are some differences amongst the two readout schemes. If the input signal is small, a large feedback resistance is needed for the trans-impedance to produce a utilizable output voltage. With the charge-integrator circuit, the timing can be changed by modulating the switch to enable longer readout duration for smaller input signals. At the same time, the reset switch in the charge integrator circuit can give rise to large switching noise which can be a disadvantage for low noise applications like digital breast tomosynthesis. Another advantage of the transimpedance amplifier is that the large integration feedback capacitor can be elimated making it cheaper for fabrication.

### Voltage-Mode Active Pixel Sensor and MOSFET Readout Circuit

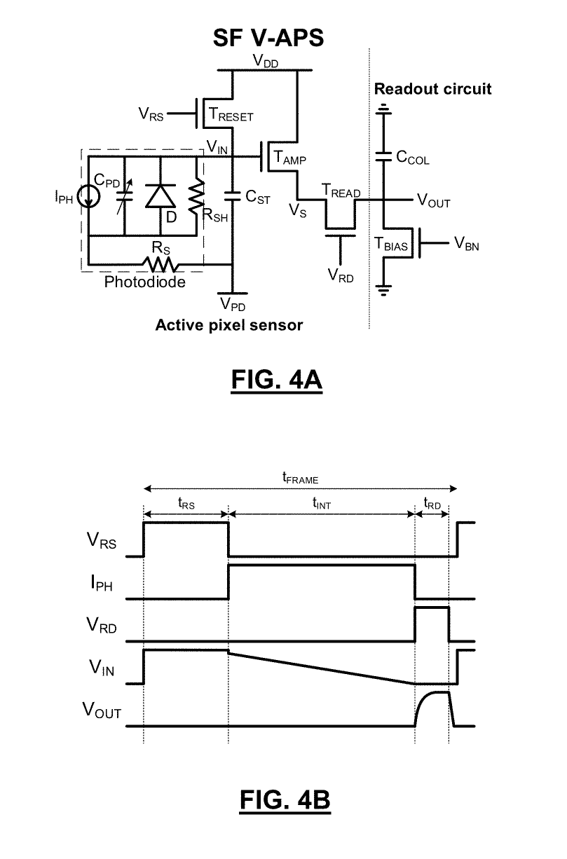

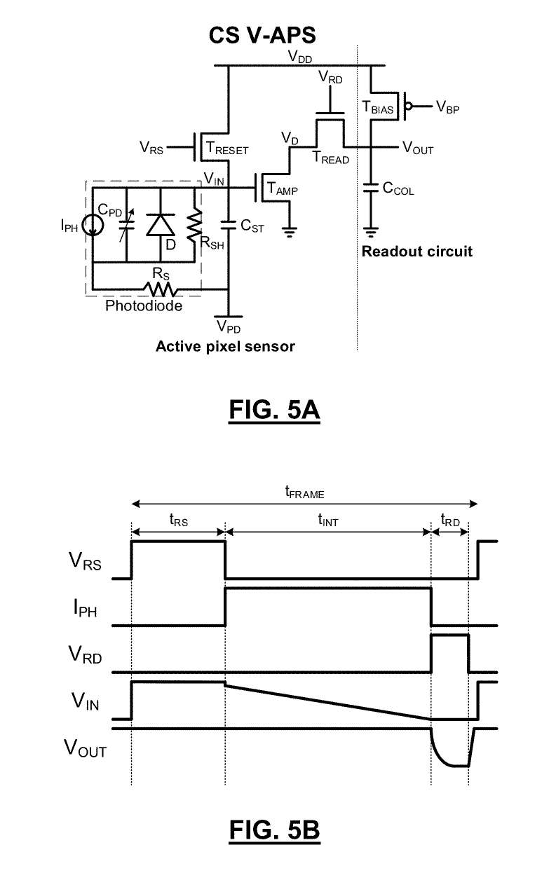

FIGS. 4A and 4B and FIGS. 5A and 5B show the pixel sensor schematics and corresponding timing diagrams for SF and CS V-APS, respectively. In this example, the APS consists of one PD, one storage capacitor/capacitance (C_{ST}), and three a-ITZO TFTs (T_{RESET}, T_{AMP}, and T_{READ}). The PD detects photoinduced signals (electrons) caused by photons emitted by a scintillator subjected to X-ray radiation. Both C_{ST} and C_{PD} (represent pixel sensor total capacitance C_{PIX}) store detected photoinduced signals. T_{RESET} is used to remove photoinduced signals stored in C_{PIX} (i.e., to reset the gate voltage of T_{AMP}, V_{IN}, to an initial value). T_{AMP} is operated to amplify detected photoinduced signals. T_{READ} controls the transfer of amplified photoinduced signals from the pixel sensor to the external readout circuit.

The readout circuit is composed of one n-type or p-type MOSFET (T_{BIAS}, n-MOSFET and p-MOSFET for SF V-APS and CS V-APS, respectively) and a column capacitor/capacitance (C_{COL}), which includes the column wire capacitor and total gate-to-source capacitors (C_{GS}) of T_{READ}. T_{BIAS} acts as an active load and C_{COL} stores readout voltages (V_{OUT}).

For large-area imaging applications, such as X-ray imagers, the operation for illustrated APS is divided into three periods, reset (t_{RS}), integration (t_{INT}), and readout (t_{RD}).

Reset Period: V_{RS} is high (10 V) to turn ON T_{RESET} and V_{RD} is low (−5 V) to keep T_{READ} OFF. Hence, electrons (photoinduced signals) stored in C_{PIX} are removed to V_{DD} through T_{RESET}. At the same time, V_{IN} (the PD cathode) increases to V_{DD} (stored by C_{ST} and C_{PD}, i.e., C_{PIX}). A reverse-biased condition for PD (anode: V_{PD}, cathode: V_{DD}; V_{DD}>V_{PD}) is hence established. To prevent I_{OFF} of T_{READ}, which is very low, from affecting V_{OUT}, the always-on n-type T_{BIAS} in SF V-APS maintains V_{OUT} at ground; the always-on p-type T_{BIAS} in CS V-APS keeps V_{OUT} at V_{DD}.

Integration Period: Both V_{RS} and V_{RD} are low (−5 V) to turn OFF T_{RESET} and T_{READ}, respectively. In the meantime, X-rays are projected on APS and absorbed by a scintillator, which subsequently releases photons. These photons strike PD generating electron-hole pairs, which are separated into electrons and holes by the electrical field inside PD. Different flux of photons induces different quantities of electron-hole pairs. Holes move toward to the low-voltage PD anode/V_{PD}; electrons are attracted by the high-voltage PD cathode/V_{IN} and stored in C_{PIX}. The movement of holes and electrons forms PD photocurrents flowing from the PD cathode to the PD anode, which accordingly decreases V_{IN} during t_{INT}. Again, to prevent I_{OFF} of T_{READ} from affecting V_{OUT}, the always-on T_{BIAS} in SF V-APS and in CS V-APS holds V_{OUT} at ground and at V_{DD}, respectively.

Readout Period: V_{RS} is still low (−5 V) to turn OFF T_{RESET} and V_{RD} goes high (10 V) to activate T_{READ}, and V_{IN} obtained by the end of integration period are converted into a corresponding V_{OUT}, which is then processed by the external circuitry and software to display X-ray images. The V_{IN}-to-V_{OUT} conversion process in SF V-APS is different from that in CS V-APS. In SF V-APS, T_{AMP} drains out a current flowing into the readout circuit through T_{READ}, so COOL is thus charged up from the ground level to higher voltages based on different V_{IN}, namely, a higher V_{IN} results in a higher V_{OUT}. In CS V-APS, T_{AMP} sinks a current from the readout circuit through T_{READ}, so that C_{COL} is hence discharged from V_{DD} to lower voltages based on different V_{IN}, which means that a higher V_{IN} leads to a lower V_{OUT}.

### Current-Mode Active Pixel Sensor and Readout Circuit

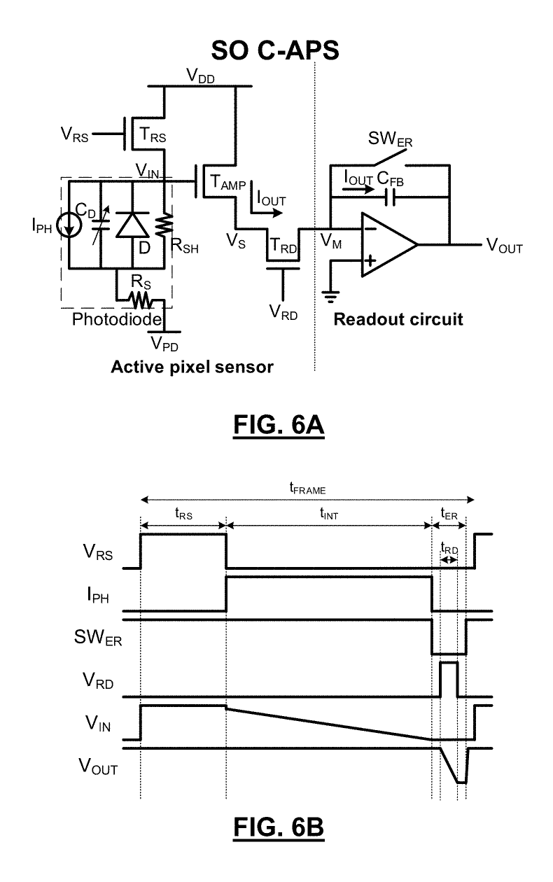

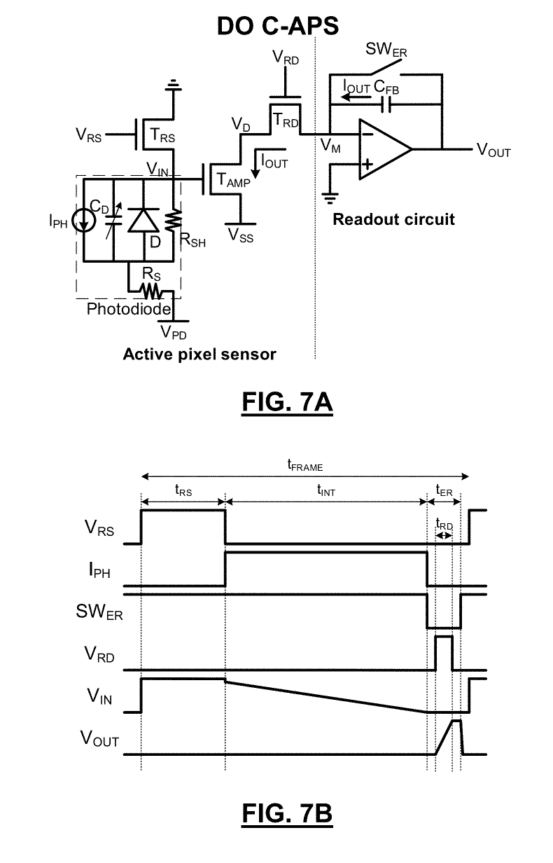

FIGS. 6A and 6B and FIGS. 7A and 7B show pixel sensor schematics and corresponding examples of timing diagrams for TA SO and TA DO C-APS, respectively. The APS consists of one a-Si PD and three a-ITZO TFTs (T_{RS}, T_{AMP}, and T_{RD}). TA SO C-APS generates currents flowing into the readout circuit and requires four voltage signal lines (V_{DD}, V_{PD}, V_{RS}, and V_{RD}). On the other hand, TA DO C-APS sinks currents flowing out of the readout circuit and requires five voltage signal lines (V_{DD}, V_{PD}, V_{RS}, V_{RD}, and ground). Due to the opposite current directions in both C-APS, the polarities of voltages generated by the readout circuit are also inverse. The circuit model for the a-Si PD is composed of a basic diode (D), a shunt resistor (R_{SH}) that can affect the reverse-biased dark current (I_{DARK}), a photodiode capacitor (C_{D}), a current source (I_{PH}) imitating photocurrents (photo-induced signals) impinging on the a-Si PD, and a series resistor (R_{S}) that dominates the forward-biased current-voltage (I-V) characteristics. C_{D} and all parasitic capacitors (C_{PAR}), such as gate-to-drain and gate-to-source capacitors (C_{GD} and C_{GS}) of T_{AMP} and C_{GS} of T_{RS}, connected to the a-Si PD cathode will store photo-induced signals. In C-APS, T_{RS} is used to reset the photo-induced signals accumulated in C_{D} and C_{PAR} (i.e. pixel capacitor, C_{PIX}=C_{D}+C_{PAR}) to zero. T_{AMP} amplifies detected photo-induced signals and acts as a constant current source (I_{OUT}) whose value is controlled by its gate voltage (V_{IN}). T_{RD} is treated like an access controlling the connection between APS and the external readout circuitry.

In terms of readout circuitries, both charge integrator and transimpedance amplifier can be considered to convert currents into voltages. In this example, a charge integrator is used, which includes an operational amplifier (OPAMP), a feedback capacitor (C_{FB}), and an external reset switch (SW_{ER}). The OPA provides a high gain to sustain the virtual short between its positive and negative inputs. Herein, the positive input of the OPA is connected to ground, which implies that the negative input can be seen as a virtual ground. C_{FB} integrates I_{OUT} to produce readout voltages (V_{OUT}) used for reconstructing x-ray images by the back-end signal processing. SW_{ER} is used to reset V_{OUT}.

The operation of TA SO C-APS, containing three stages, reset (t_{RS}), integration (t_{INT}), and readout (t_{RD}) is described as follows.

Reset stage: V_{RS} and V_{RD} are set at high and low levels, respectively, so that T_{RS} is on and T_{RD} is off to isolate APS and the charge integrator (e.g. the readout circuit) from each other. Hence, detected electrons in the last frame, stored by C_{PIX}, are forced to move to V_{DD}, a high-voltage source, through T_{RS}, increasing the gate voltage of T_{AMP} (V_{IN}, also the cathode voltage of the a-Si PD) to V_{DD}. Because V_{PD}, the anode voltage of the a-Si PD, is set to a value lower than V_{DD}, the a-Si PD is reversely biased (ensuring the device is operated in photoconductive mode). At the same time, for both TA SO and TA DO C-APS, SW_{ER} is activated, so V_{OUT} is shorted to the negative input (V_{M}) of the OPA which is a virtual ground. V_{OUT} is hence kept at the ground level.

Integration stage: V_{RS} is set low to turn off T_{RS} and V_{RD} remains at low level to keep T_{RD} off. Next, photons, produced by the CsI:Tl scintillator under x-ray exposure, will impinge the a-Si PD, leading to the production of photo-induced electrons-hole pairs which are then separated to electrons and holes by the reverse bias established during Reset Stage. Electrons go to the high-voltage a-Si PD cathode/V_{IN} and are stored in C_{PIX}; holes are driven to the low-voltage a-Si PD anode/V_{PD}. The resulting photocurrents, flowing from the cathode to anode, will decrease V_{IN} during t_{INT}. V_{OUT} remains shorted to V_{M}, the virtual ground. t_{INT} can be adjusted for a given applications.

Readout stage: Before APS and the charge integrator are connected together, SW_{ER} must be turned off, which allows C_{FB} to integrate I_{OUT} to produce V_{OUT}. Then, V_{RS} is still held at low and V_{RD} changes to high to turn T_{RD} on. For TA SO C-APS, the source voltage (V_{S}) of T_{AMP} is fixed during Read stage because of the connection with V_{M}, and T_{AMP} produces I_{OUT} flowing into the charge integrator through T_{RD}. Since V_{DD} is higher than V_{IN} minus the threshold voltage of T_{AMP} (V_{TH}_{_}_{AMP}), acquired at the end of Integration stage, T_{AMP} is operated in saturation region.

Hence, I_{OUT} can be expressed as:

$${I}_{OUT} = \frac{1}{2} {μ}_{EFF} {C}_{OX} \frac{W}{L} {( {V}_{IN} - {V}_{S} - {V}_{TH \_ AMP} )}^{2} \qquad ( 1 )$$

where μ_{EFF} is the field-effect mobility, C_{OX} is the oxide capacitance per unit area, and W and L are the channel width and length of T_{AMP}, respectively. V_{OUT} can be calculated by:

$${I}_{OUT} {t}_{RD} = {C}_{FB} ( {V}_{M} - {V}_{OUT} ) = {I}_{OUT} {t}_{RD} = {C}_{FB} ( 0 - {V}_{OUT} ) ⇒ {V}_{OUT} = - \frac{{I}_{OUT} {t}_{RD}}{{C}_{FB}} \qquad ( 2 )$$

Notably, V_{OUT} is negative in TA SO C-APS. For TA DO C-APS, the drain voltage (V_{D}) of T_{AMP} is fixed during Readout stage because of the connection with V_{M}, and T_{AMP} produces I_{OUT} flowing out of the charge integrator via T_{READ}. V_{D} and V_{IN} can influence the operation region of T_{AMP} and thus I_{OUT} calculation. If V_{D}>(V_{IN}−V_{TH}), I_{OUT} can be computed by:

$${I}_{OUT} = \frac{1}{2} {μ}_{EFF} {C}_{OX} \frac{W}{L} [ 2 ( {V}_{IN} - {V}_{SS} - {V}_{TH \_ AMP} ) ( {V}_{D} - {V}_{SS} ) - {( {V}_{D} - {V}_{SS} )}^{2} ] \qquad ( 3 )$$

where V_{SS} is the source voltage of T_{AMP}. If V_{D}<(V_{IN}−V_{TH}), I_{OUT} can be given by:

$${I}_{OUT} = \frac{1}{2} {μ}_{EFF} {C}_{OX} \frac{W}{L} {( {V}_{IN} - {V}_{SS} - {V}_{TH \_ AMP} )}^{2} \qquad ( 4 )$$

V_{OUT} can also be calculated by:

$${I}_{OUT} {t}_{RD} = {C}_{FB} ( {V}_{OUT} - {V}_{M} ) ⇒ {V}_{OUT} = \frac{{I}_{OUT} {t}_{RD}}{{C}_{FB}} \qquad ( 5 )$$

In contrast with TA SO C-APS, V_{OUT} is positive in TA DO C-APS. From the system design point of view, for a given I_{OUT}, which is controlled by C-APS, adjusting t_{RD} and C_{FB} values can modulate V_{OUT}, which is then translated into digital number (DN representing grayscale) by analog-to-digital converters (ADCs) by the back-end signal processing.

The timing diagram used here is based on a rolling shutter method. Reset Stage for pixels in x-ray imagers is executed row-by-row, starting from the top to the bottom of TFT arrays; when reset for pixels in the last rows is done, Readout Stage of pixels then also proceeds row-by-row from the top to the bottom of TFT arrays. For a row of pixels, the timing gap between Reset Stage and Readout Stage means t_{INT} (Integration stage).

### Active Pixel Sensor and Transimpedance Amplifier

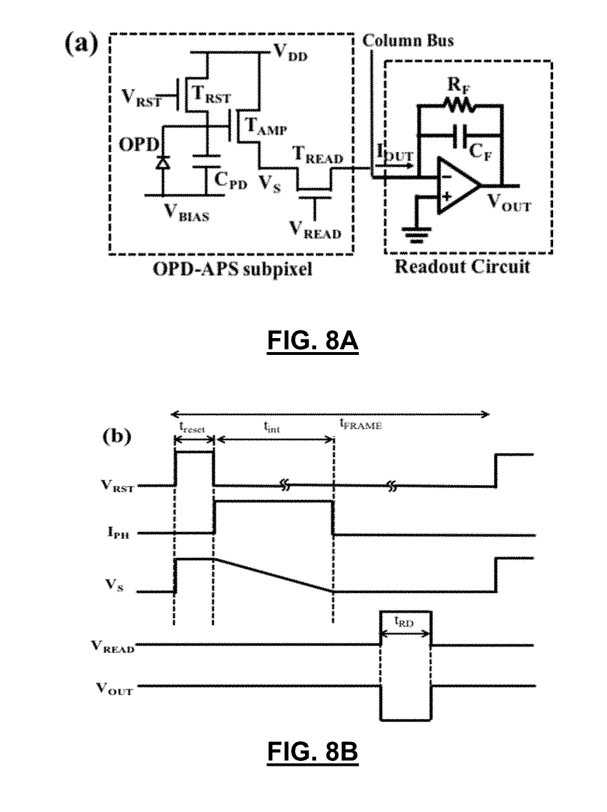

FIGS. 8A-B show the pixel sensor schematics and corresponding timing diagrams for an embodiment using an a-ITZO APS and a TIA readout circuit. The APS consists of one PD, one storage capacitor (C_{ST}), and three a-ITZO TFTs (T_{RESET}, T_{AMP}, and T_{READ}). The PD detects photo-induced signals (electrons) caused by photons absorbed by an OPD layer. Both C_{ST} and C_{PD} (represent pixel sensor total capacitance, C_{PIX}) store detected photo-induced signals. T_{RESET} is used to remove photo-induced signals stored in C_{PIX} (i.e. to reset the gate voltage of T_{AMP}, V_{IN}, to an initial value). T_{AMP} is operated to amplify detected photo-induced signals. T_{READ} controls the transfer of amplified photo-induced signals from the pixel sensor to the external readout circuit.

For large-area imaging applications, such as X-ray imagers, the operation for illustrated APS is divided into three periods, reset (t_{RS}), integration (t_{INT}), and readout (t_{RD}):

Reset period: V_{RS} is set high (10 V) to turn on T_{RESET} and V_{RD} is low (−5 V) to keep T_{READ} off to isolate APS from the TIA readout circuit. Next, electrons (photo-induced signals) stored in C_{PIX} are moved to V_{DD} through T_{RST}. Hence, V_{IN} (the PD cathode) increases to V_{DD}. A reverse-biased condition for OPD (anode: V_{PD}, cathode: V_{DD}; V_{DD}>V_{PD}) is kept while Vout is kept at the ground level.

Integration period: Both V_{RS} and V_{RD} are set low (−5 V) to turn off T_{RST} and T_{READ}, respectively. In the meantime, illuminated light (e.g. X-rays) are absorbed by OPD and generate excitons. These excitons are dissociated into electron-hole pairs which are separated into electrons and holes by the electrical field inside OPD formed by reverse bias. Different flux of photons induces different quantities of electron-hole pairs. Holes move toward to the low-voltage PD anode/V_{PD}; electrons are attracted by the high-voltage PD cathode/V_{IN} and stored in C_{PIX}. The movement of holes and electrons forms PD photocurrents flowing from the PD cathode to the PD anode, which accordingly decreases V_{IN} during t_{INT}.

Readout period: V_{RS} is kept low (−5 V) to turn off T_{RST} and V_{RD} goes high (10 V) to activate T_{READ}, and V_{IN} obtained by the end of integration period are converted into a corresponding V_{OUT} which is then processed by the TIA external circuit. The source voltage (V_{S}) of T_{AMP} is fixed during readout stage because of the connection with TIA, and T_{AMP} produces I_{OUT} flowing into the TIA external circuit through T_{RD}. Since V_{DD} is higher than Vin minus the threshold voltage of T_{AMP} (V_{TH}_{_}_{AMP}) acquired at the end of Integration stage, T_{AMP} is operated in saturation region. Hence, I_{OUT} can be expressed as:

$${I}_{OUT} = {μ}_{eff} {C}_{ox} \frac{W}{2 L} {( {V}_{IN} - {V}_{S} - {V}_{TH \_ AMP} )}^{2} \qquad ( 1 )$$

where μ_{eff} is the field-effect mobility, and W and L are the channel width and length of T_{AMP}, respectively. V_{OUT} can be calculated by:

V_{OUT}=−I_{OUT}R_{F} (2)

By knowing the maximum expected I_{OUT}, R_{F} is selected to optimize the signal-to-noise ratio.

The capacitance C_{F} between the OP Amps inverting input and V_{OUT} stabilizes the circuit against potential oscillation problem or gain peaking due to impedance mismatch when operating frequency varies.

### Pixel Circuit Layout and Fabrication Process

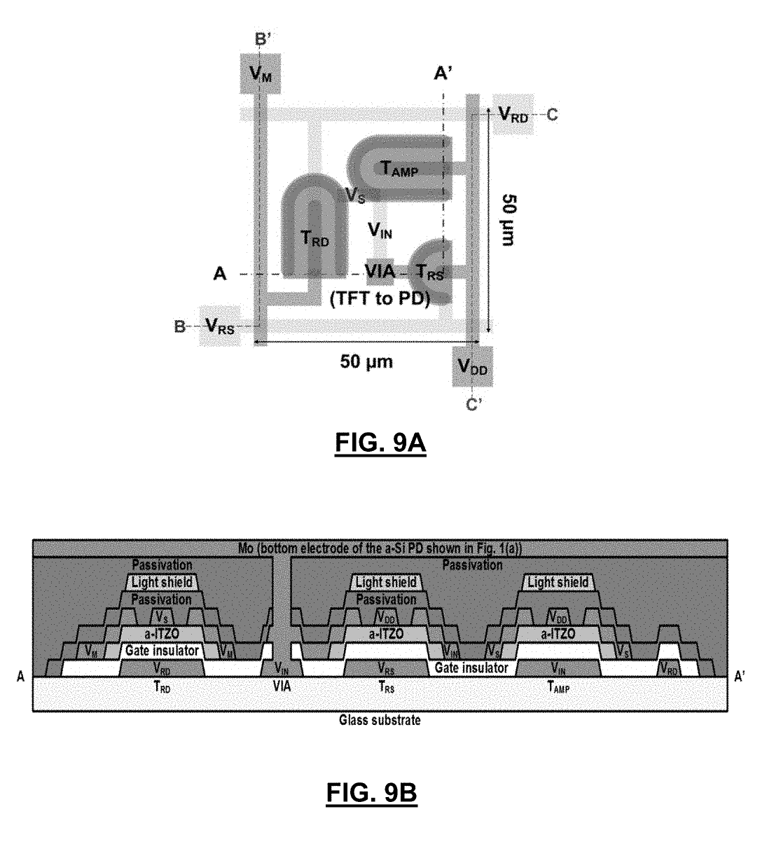

FIG. 9A illustrates a 50 μm pixel pitch layout for the a-ITZO TFT C-APS. Considering the TFT layout, the half-Corbino TFT structure with the inner-drain configuration is adopted to acquire higher operation current (I_{OUT}) for T_{AMP}. The VIA is used to connect the photodiode bottom electrode to T_{AMP} gate and T_{RS} source. V_{M} is the data line output voltage connected to the negative input node of the op-amp. On the other hand, the outer-drain bias condition is used for T_{RD} to reduce the gate-to-source capacitance and data line parasitic capacitance. The critical dimension (minimum width) of metal lines is 3 μm. FIG. 9B illustrates a cross-section view of the a-ITZO TFT C-APS layer.

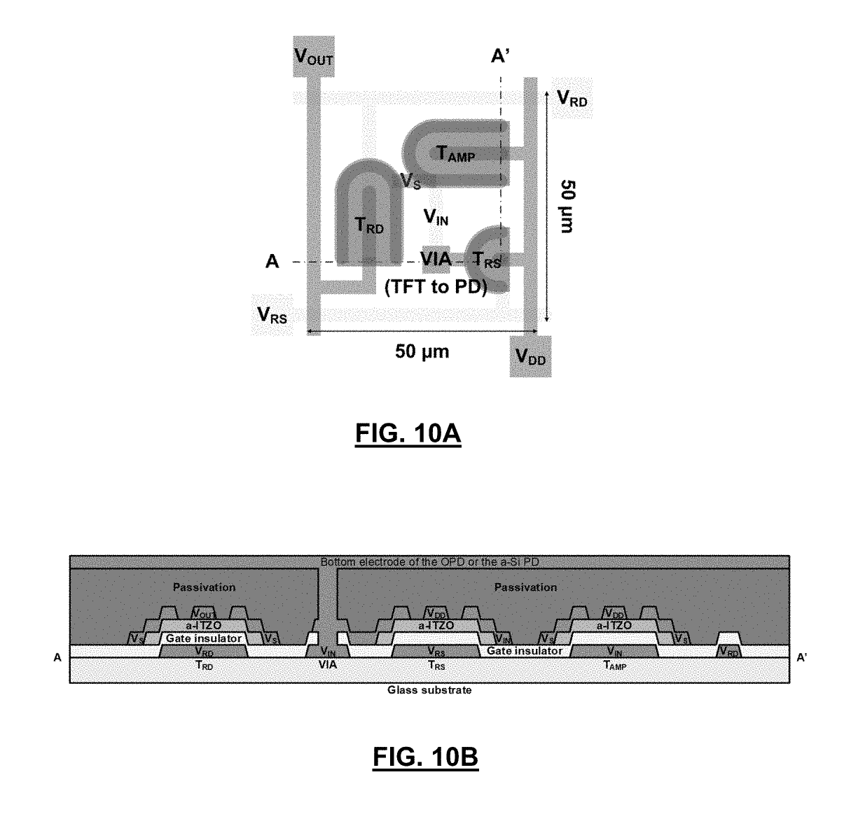

FIG. 10A illustrates a 50 μm pixel pitch layout for the a-ITZO TFT V-APS. FIG. 10B illustrates a cross-section view of the a-ITZO TFT V-APS layer.

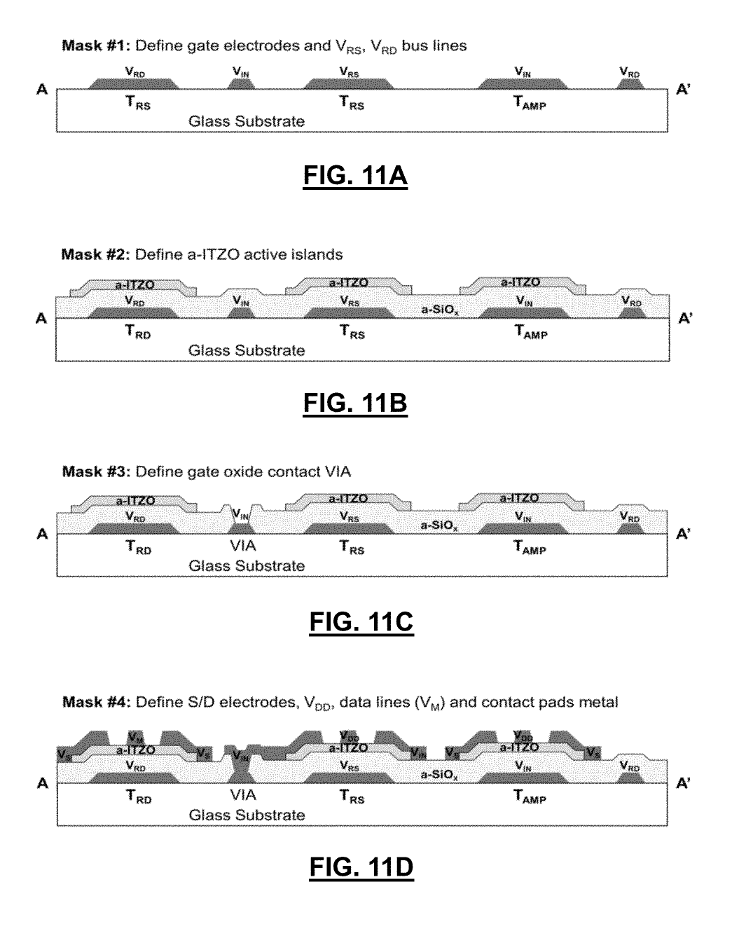

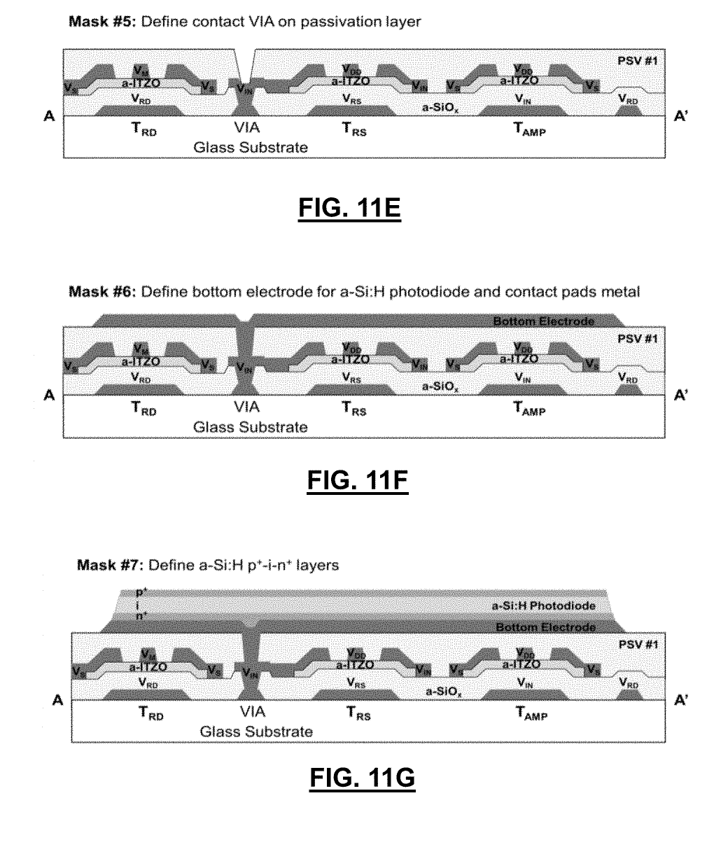

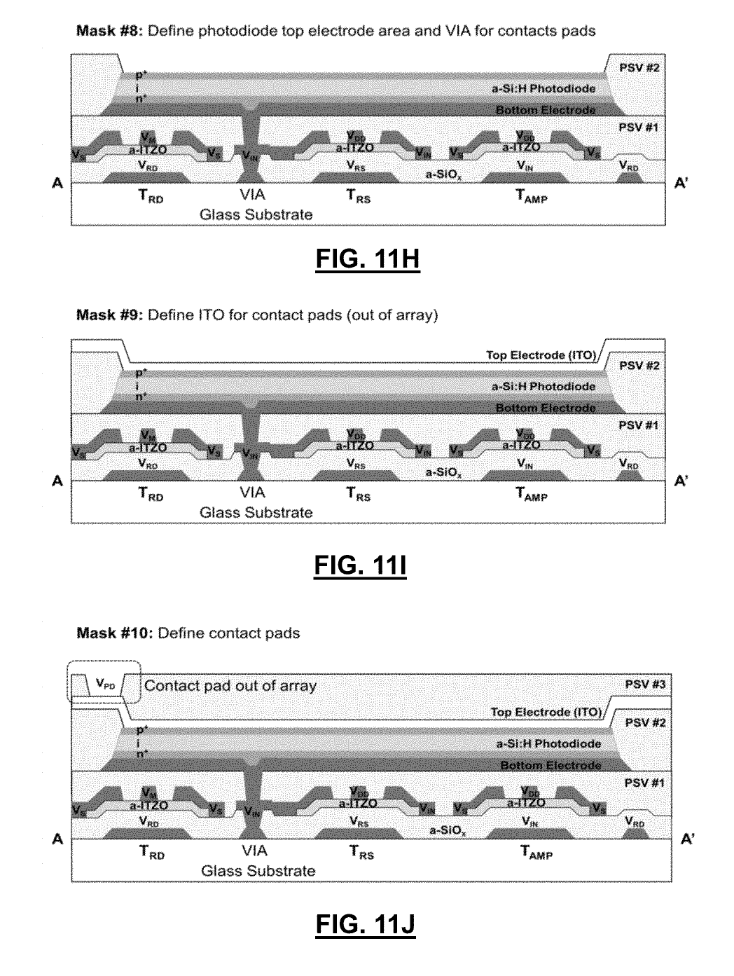

FIG. 11A-J illustrates a 10-mask processing steps and cross-sectional views (A to A′) of the C-APS pixel and the a-Si:H photodiode fabrication according to the pixel layout shown in FIG. 9A. First, metal #1 (Mo, for gate electrodes of T_{RS}, T_{AMP}, and T_{RD}, and V_{RS} and V_{RD} lines) is formed by DC sputtering on glass substrate. The standard photolithography is used for metal definition (mask #1). Next, a 470-nm amorphous silicon oxide (a-SiOₓ) as the gate insulator is deposited using PECVD. Then, a 30-nm a-ITZO films DC sputtered using the optimized O₂ flow ratio of 5%, subsequently patterned into active islands by a wet etching process (mask #2) and annealed at 300° C. The gate contact VIA is defined (mask #3) to connect V_{IN} and the gate of T_{AMP} using the reactive-ion etching (RIE). At the same time, contact VIAs for V_{RS} and V_{RD} pads are created. Afterward, metal #2 (Mo, for S/D electrodes of T_{RS}, T_{AMP}, and T_{RD} and V_{DD} and V_{M} lines) are deposited by sputtering and patterned using the back channel etch process (mask #d). A 3 μm a-SiOₓ passivation layer (PSV #1) is deposited over the fabricated a-ITZO TFTs. A contact VIA is generated using RIE (mask #5) to electrically connect the source electrode of T_{RS}/the gate electrode of T_{AMP} to the patterned bottom Mo electrode (cathode) of the a-Si:H photodiode (mask #6). Also, VIAs for the four contact pads (V_{RS}, V_{RD}, V_{M}, and V_{DD}) are etched using mask #5. The opaque bottom electrode of a-Si:H photodiode also serves as a light shield for a-ITZO TFTs. Using PECVD, a 50-nm n+ layer, a 1-μm thick undoped/intrinsic a-Si:H layer, and a 50-nm p+ layer are sequentially deposited and patterned by photolithography (mask #7). A second passivation layer (PSV #2) can be deposited on top of the p+ layer. Next, the photodiode top electrode area and VIAs for all four contact pads are defined (mask #8). A transparent indium-tin oxide (ITO) layer is deposited as the top electrode of the a-Si:H photodiode. Then, the a-Si:H photodiode is annealed at 150° C. to suppress the excess current coming from extrinsic defect generation. The ITO layer is patterned out of the active-matrix array as the top conductive layer for four contact pads (mask #9). After etching ITO, the ITO needs to be thermally annealed at around 230° C. [209]. A third passivation layer (PSV #3) is deposited to protect the entire structure. Finally, contact VIAs for pads VRS, VRD, VM, VDD and VPD are defined out of the active-matrix array by etching the PSV #3 (mask #10). A 150-μm CsI:Tl scintillator can be directly deposited (or attached using a FOP) on top of the passivated a-Si:H photodiode layer to complete the detector fabrication.

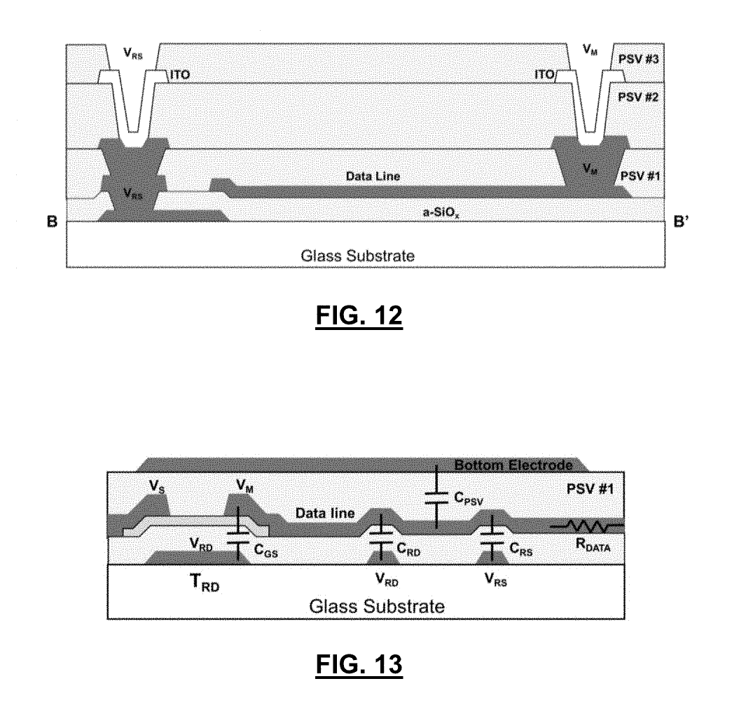

FIG. 12 shows the final cross-sectional view (B to B′) of the data line, V_{RS} and V_{M} pads after the entire process according to the pixel layout shown in FIG. 9A. The cross-sectional view (C to C′) of the V_{DD} and V_{RD} pads (not shown) is the same as FIG. 12 by replacing V_{RS} with V_{RD} and V_{M} with V_{DD}.

It should be noted that the a-Si:H photodiode bottom electrode is also used as a light shield for a-ITZO TFTs. At the same time, since the photodiode bottom electrode voltage is the same as the gate voltage of T_{AMP}, T_{AMP} behaves like a dual-gate TFT with top and bottom gates biased together.

FIG. 13 illustrates a cross-sectional schematic of T_{RD} and the data line series resistance (R_{DATA}) and parasitic capacitances (C_{DATA}). As shown in FIG. 13, based on the layout described above, C_{DATA} consists of the gate-to-source overlapping capacitance (C_{GS}) of T_{RD}, the overlapping capacitance (C_{RD}) between the data line and V_{RD}, the overlapping capacitance (C_{RS}) between the data line and V_{RS}, and the overlapping capacitance (C_{PSV}) between the data line and the a-Si:H photodiode bottom electrode. Hence, C_{DATA} can be estimated by

C_{DATA}=N(C_{G}+C_{RD}+C_{RS}+C_{PSV})=N[C_{OX}(L_{S}L+2L²)+C_{OX,PSV}(aₚᵢₓL)]

where N is the number of pixels on a data line, L is the both process critical dimension and line width (3 μm), L_{S} is the length of the T_{RD} source electrode (˜15 μm), aₚᵢₓ is the pixel pitch (50 μm), Cox is the gate oxide (470 nm a-SiOx) capacitance (7.34 nF/cm2), Cox,PSV is the passivation layer (e.g., 3 μm a-SiOx) capacitance (1.15 nF/cm2).

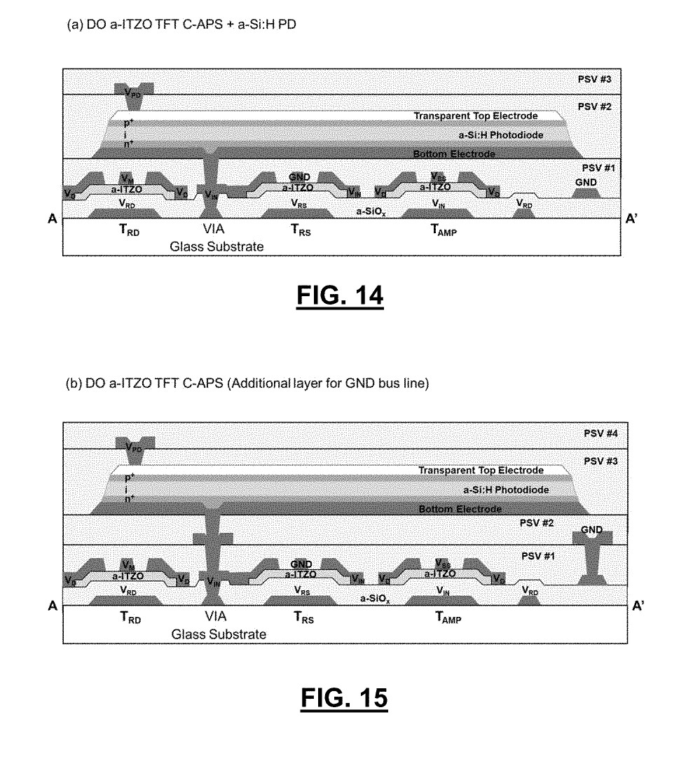

FIG. 14 illustrates a cross-sectional view of a DO a-ITZO TFT and the a-Si:H photodiode fabrication with no additional layer for GND bus line. The 10-mask processing steps for this configuration are as follows.

First, metal #1 (Mo, for gate electrodes of T_{RS}, T_{AMP}, and T_{RD}, and V_{RS} and V_{RD} lines) is formed by DC sputtering on glass substrate. The standard photolithography is used for metal definition (mask #1). Next, amorphous silicon oxide (a-SiOx) as the gate insulator is deposited using PECVD. Then, a thin a-ITZO film is DC sputtered using the optimized O₂ flow ratio of 5%, subsequently patterned into active islands by a wet etching process (mask #2) and annealed at 300° C. The gate contact VIA is defined (mask #3) to connect V_{IN} and the gate of T_{AMP} using the reactive-ion etching (RIE). At the same time, contact VIAs for V_{RS} and V_{RD} pads are created. Afterward, metal #2 (Mo, for S/D electrodes of T_{RS}, T_{AMP}, and T_{RD} and GND, V_{SS} and V_{M} lines) are deposited by sputtering and patterned using the back channel etch process (mask #4). A a-SiOx passivation layer (PSV #1) is deposited over the fabricated a-ITZO TFTs. A contact VIA is generated using RIE (mask #5) to electrically connect the source electrode of T_{RS}/the gate electrode of T_{AMP} to the patterned bottom Mo electrode (cathode) of the a-Si:H photodiode (mask #6). Also, VIAs for the five contact pads (GND, V_{RS}, V_{RD}, V_{M}, and V_{SS}) are etched using mask #5. The opaque bottom electrode of a-Si:H photodiode also serves as a light shield for a-ITZO TFTs. Using PECVD, a 50-nm n+ layer, a 1-μm thick undoped/intrinsic a-Si:H layer, and a 50-nm p+ layer are sequentially deposited and patterned by photolithography (mask #7). A second passivation layer (PSV #2) can be deposited on top of the p+ layer. Next, the photodiode top electrode area and VIAs for all four contact pads are defined (mask #8). A transparent indium-tin oxide (ITO) layer is deposited as the top electrode of the a-Si:H photodiode. Then, the a-Si:H photodiode is annealed at 150° C. to suppress the excess current coming from extrinsic defect generation. The ITO layer is patterned out of the active-matrix array as the top conductive layer for four contact pads (mask #9). After etching ITO, the ITO needs to be thermally annealed at around 230° C. A third passivation layer (PSV #3) is deposited to protect the entire structure. Finally, contact VIAs for pads GND, V_{RS}, V_{RD}, V_{M}, V_{SS} and V_{PD} are defined out of the active-matrix array by etching the PSV #3 (mask #10). A 150-nm CsI:Tl scintillator can be directly deposited (or attached using a FOP) on top of the passivated a-Si:H photodiode layer to complete the x-ray detector fabrication.

FIG. 15 illustrates a cross-sectional view of a DO a-ITZO TFT and the a-Si:H photodiode fabrication with an additional layer for GND bus line. The 12-mask processing steps for this configuration are as follows.

First, metal #1 (Mo, for gate electrodes of T_{RS}, T_{AMP}, and T_{RD}, and V_{RS} and V_{RD} lines) is formed by DC sputtering on glass substrate. The standard photolithography is used for metal definition (mask #1). Next, amorphous silicon oxide (a-SiOx) as the gate insulator is deposited using PECVD. Then, a thin a-ITZO film is DC sputtered using the optimized O₂ flow ratio of 5%, subsequently patterned into active islands by a wet etching process (mask #2) and annealed at 300° C. The gate contact VIA is defined (mask #3) to connect V_{IN} and the gate of T_{AMP} using the reactive-ion etching (RIE). At the same time, contact VIAs for V_{RS} and V_{RD} pads are created. Afterward, metal #2 (Mo, for S/D electrodes of T_{RS}, T_{AMP}, and T_{RD} and GND, V_{SS} and V_{M} lines) are deposited by sputtering and patterned using the back channel etch process (mask #4). A a-SiOx passivation layer (PSV #1) is deposited over the fabricated a-ITZO TFTs. Contact VIAs for gate electrode of T_{AMP} (V_{IN}) and GND bus line are generated using RIE (mask #5). GND bus lines are deposited and defined on top of PSV #1 (mask #6) followed by deposition of another PSV layer (PSV #2), VIA for V_{IN} is defined (mask #7) to electrically connect the source electrode of T_{RS}/the gate electrode of T_{AMP} to the patterned bottom Mo electrode (cathode) of the a-Si:H photodiode (mask #8). Also, VIAs for the five contact pads (GND, V_{RS}, V_{RD}, V_{M}, and V_{SS}) are etched using mask #7. The opaque bottom electrode of a-Si:H photodiode also serves as a light shield for a-ITZO TFTs. Using PECVD, a 50-nm n+ layer, a 1-μm thick undoped/intrinsic a-Si:H layer, and a 50-nm p+ layer are sequentially deposited and patterned by photolithography (mask #9). A third passivation layer (PSV #3) can be deposited on top of the p+ layer. Next, the photodiode top electrode area and VIAs for all four contact pads are defined (mask #10). A transparent indium-tin oxide (ITO) layer is deposited as the top electrode of the a-Si:H photodiode. Then, the a-Si:H photodiode is annealed at 150° C. to suppress the excess current coming from extrinsic defect generation. The ITO layer is patterned out of the active-matrix array as the top conductive layer for four contact pads (mask #11). After etching ITO, the ITO needs to be thermally annealed at around 230° C. The last passivation layer (PSV #4) is deposited to protect the entire structure. Finally, contact VIAs for pads GND, V_{RS}, V_{RD}, V_{M}, V_{SS} and V_{PD} are defined out of the active-matrix array by etching the PSV #3 (mask #12). A 150-μm CsI:Tl scintillator can be directly deposited (or attached using a FOP) on top of the passivated a-Si:H photodiode layer to complete the x-ray detector fabrication.

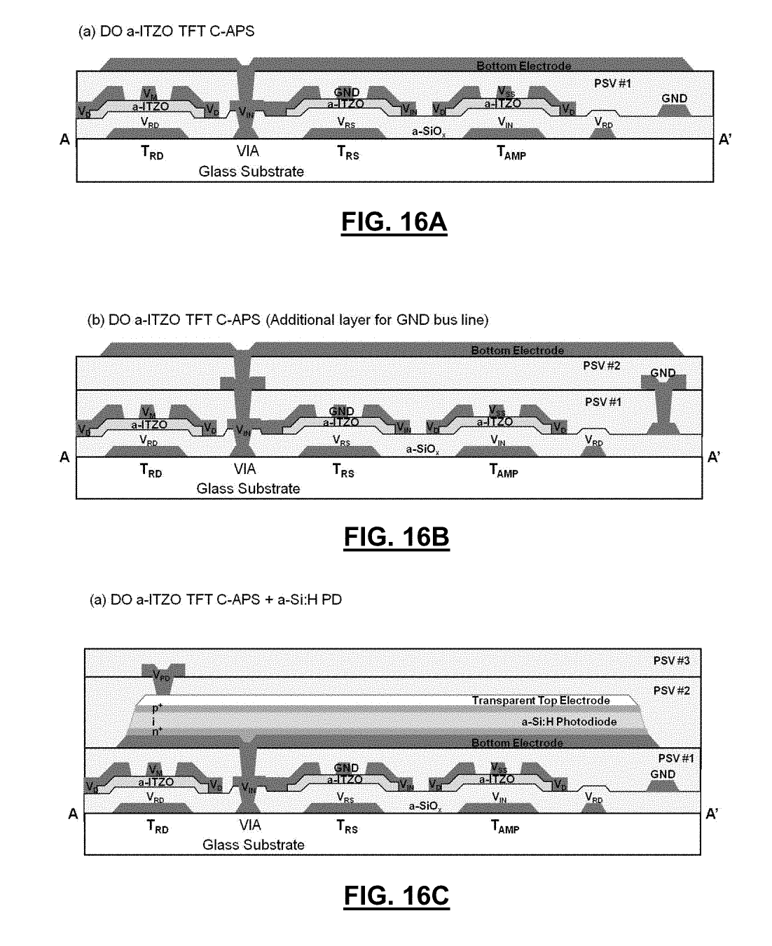

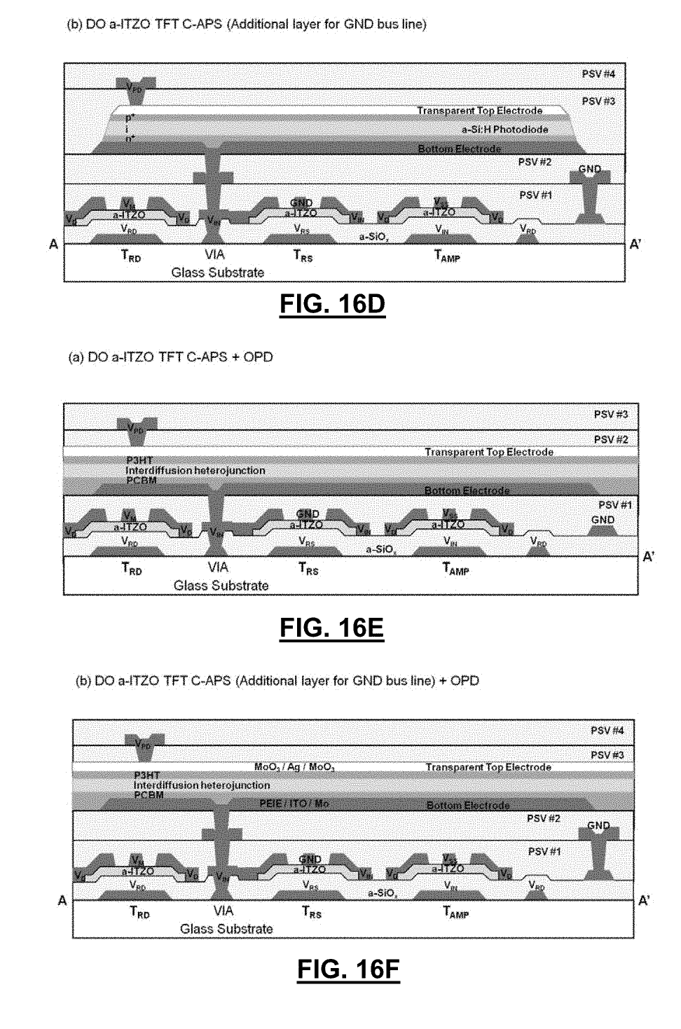

FIGS. 16A-F illustrate various cross-sections for an a-ITZO TFT C-APS. FIG. 16A illustrates a cross-section of a DO a-ITZO TFT C-APS (no photodiode) with a GND bus line on S/D layer. FIG. 16B illustrates a cross-section of a DO a-ITZO TFT C-APS (no photodiode) with a GND bus line on a separate layer. FIG. 16C illustrates a cross-section of DO a-ITZO TFT C-APS (w/a-Si:H photodiode) with a GND bus line on S/D layer. FIG. 16D illustrates a cross-section of a DO a-ITZO TFT C-APS (w/a-Si:H photodiode) with a GND bus line on a separate layer. FIG. 16E illustrates a cross-section of a DO a-ITZO TFT C-APS (w/OPD) with a GND bus line on S/D layer. FIG. 16F illustrates a cross-section of a DO a-ITZO TFT C-APS (w/OPD) with a GND bus line on a separate layer.

### Current-Mode Active Pixel Sensor for Direct Imaging

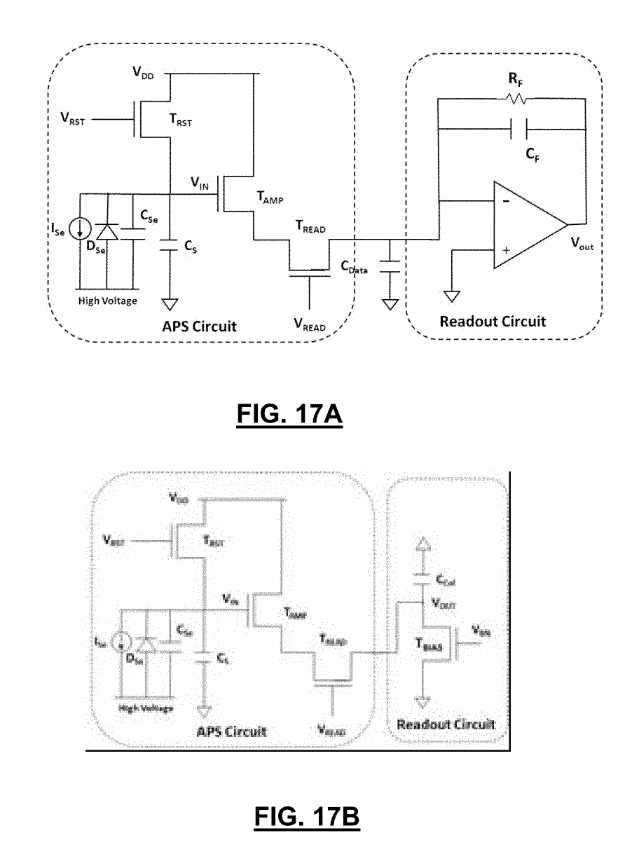

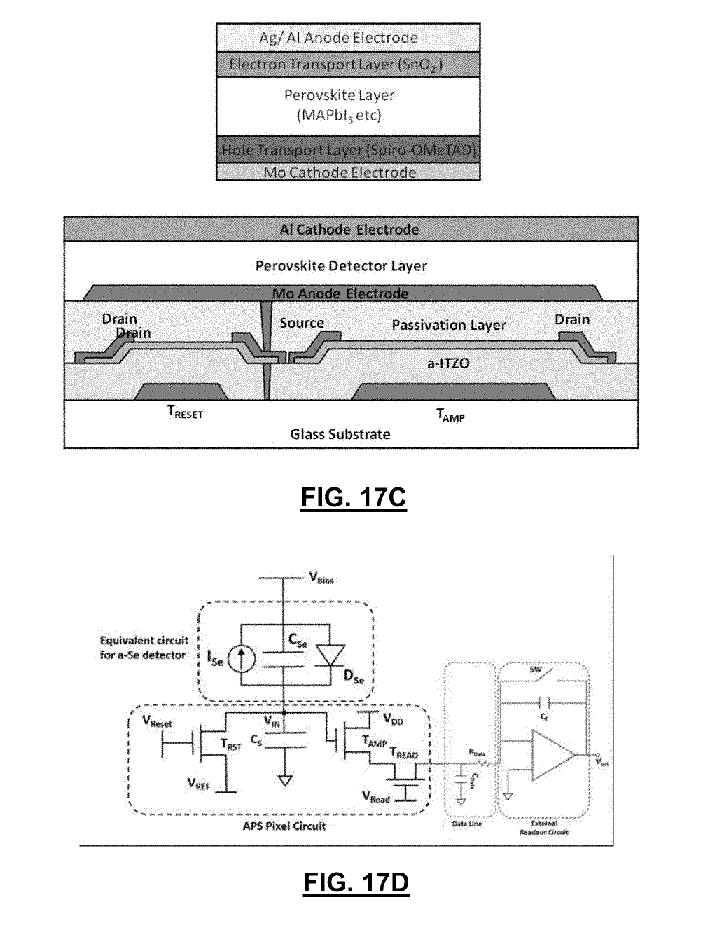

The disclosed TFT APS may be integrated with photodetectors configured for direct image sensing. In one example, a-Se detector is incorporated with a current-mode APS (C-APS) backplane. A schematic of an equivalent circuit this a-Se a 3-TFT C-APS imager is shown in FIGS. 17A-B. FIG. 17A illustrates a top cathode APS circuit schematic with, for example, a trans-impedance amplifier readout circuit (R_{F} and C_{F} are the feedback resistor and capacitor). The C-APS circuit consists of three TFTs—reset, amplifying and read (T_{RST}, T_{AMP} and T_{READ}). In the reset mode, only T_{RST} is switched on (by V_{RST}), which sets the voltage V_{IN} to V_{REF}. Next, in the integration mode, the charge generated due to the incident x-rays accumulates on the storage capacitor (Cₛ), which changes the voltage V_{IN}. After the integration stage, T_{READ} is switched on (by V_{READ}), which transfers an amplified signal (through T_{AMP}) to the data-line and external readout circuit. Thus, the APS circuit provides a charge gain, which cannot reduce the effect of any pre-amplifying noise (originating from T_{RST} leakage current shot noise and reset noise), but can eliminate the influence of the post-amplifying noise (thermal and flicker noise from T_{AMP} and T_{READ} and external readout circuit noise). FIG. 17B illustrates a top cathode Source follower V-APS circuit schematic with, for example, a MOS-based readout circuit. In this case, T_{BIAS} in the readout circuit acts as an active load and C_{col} stores the readout voltage, V_{OUT}. The a-Se detector layer is represented by a current source (Iₛₑ), diode (Dₛₑ) and the capacitance related to it (Cₛₑ). FIG. 17C illustrates cross-sectional views of a-Se imager and FIG. 17D illustrates a circuit diagram for a-Se/a-IGZO TFT APS. Other photodetectors such as, but not limited to, mercury iodine or perovskites detectors may be used.

It is to be understood that the foregoing description is of one or more embodiments of the invention. The invention is not limited to the particular embodiment(s) disclosed herein, but rather is defined solely by the claims below. Furthermore, the statements contained in the foregoing description relate to the disclosed embodiment(s) and are not to be construed as limitations on the scope of the invention or on the definition of terms used in the claims, except where a term or phrase is expressly defined above. Various other embodiments and various changes and modifications to the disclosed embodiment(s) will become apparent to those skilled in the art.

As used in this specification and claims, the terms “e.g.,” “for example,” “for instance,” “such as,” and “like,” and the verbs “comprising,” “having,” “including,” and their other verb forms, when used in conjunction with a listing of one or more components or other items, are each to be construed as open-ended, meaning that the listing is not to be considered as excluding other, additional components or items. Other terms are to be construed using their broadest reasonable meaning unless they are used in a context that requires a different interpretation.

1. An active pixel sensor, comprising:
thin-film transistors (TFTs) fabricated on a glass substrate, the TFTs comprising:
a gate electrode patterned on the glass substrate;
a gate insulator layer disposed over the gate electrode;
an amorphous indium-tin-zinc-oxide (a-ITZO) active semi-conductor layer disposed on the gate insulator layer and patterned over the gate electrode; and
a source electrode and a drain electrode patterned from a metal layer deposited over the a-ITZO layer.

2. The active pixel sensor of claim 1, wherein the TFTs form an active pixel sensor circuit that includes a reset TFT, an amplifier TFT, and a readout TFT.

3. The active pixel sensor of claim 1, wherein the TFTs form a source output current-mode active pixel sensor circuit that includes a reset TFT, an amplifier TFT, and a readout TFT.

4. The active pixel sensor of claim 1, wherein the TFTs form a drain output current-mode active pixel sensor circuit that includes a reset TFT, an amplifier TFT, and a readout TFT.

5. The active pixel sensor of claim 1, wherein the TFTs form a source follower voltage-mode active pixel sensor circuit that includes a reset TFT, an amplifier TFT, and a readout TFT.

6. The active pixel sensor of claim 1, wherein the TFTs form a common source voltage-mode active pixel sensor circuit that includes a reset TFT, an amplifier TFT, and a readout TFT.

7. The active pixel sensor of claim 1 having a pixel pitch of 50 μm.

8. The active pixel sensor of claim 1, further comprising a photodiode layer fabricated over the over the TFTs forming a vertically-stacked imaging pixel.

9. The active pixel sensor of claim 8, wherein the photodiode is an organic photodiode or an amorphous Silicon p+-i-n+ Photodiode.

10. The active pixel sensor of claim 1, further comprising a photoconductive material layer fabricated over the over the TFTs forming a vertically-stacked imaging pixel.

11. The active pixel sensor of claim 10, wherein the photoconductive material is amorphous selenium, mercury iodide, or organometallic halide perovskite.

12. An active pixel sensor imaging array for large-area x-ray imagers, the array comprising:
a plurality of active pixel sensors arranged in rows and columns, wherein each of the plurality of active pixel sensors are coupled to an external readout circuit and include a reset thin-film transistors (TFT), an amplifier TFT, and a readout TFT fabricated on a glass substrate, each of the TFTs comprising:
a gate electrode patterned on the glass substrate;
a gate insulator layer disposed over the gate electrode;
an amorphous indium-tin-zinc-oxide (a-ITZO) active semi-conductor layer disposed on the gate insulator layer and patterned over the gate electrode; and
a source electrode and a drain electrode patterned from a metal layer deposited over the a-ITZO layer;
a photodetector fabricated over each of the active pixel sensors to form a vertically-stacked imaging pixel.

13. The active pixel sensor imaging array of claim 12, wherein the photodetector includes a photodiode layer or a photoconductive material layer.

14. The active pixel sensor imaging array of claim 12, wherein each of the plurality of active pixel sensors has a pixel pitch of 50 μm.

15. An x-ray imaging device, comprising:
an active pixel sensor imaging array having a plurality of active pixel sensors arranged in rows and columns, each of the plurality of active pixel sensors include thin-film transistors (TFTs) fabricated on a glass substrate, the TFTs comprising:
a gate electrode patterned on the glass substrate;
a gate insulator layer disposed over the gate electrode;
an amorphous indium-tin-zinc-oxide (a-ITZO) active semi-conductor layer disposed on the gate insulator layer and patterned over the gate electrode; and
a source electrode and a drain electrode patterned from a metal layer deposited over the a-ITZO layer;
a photodetector fabricated over the over each active pixel sensor forming vertically-stacked imaging pixel; and
a readout circuit coupled to each of the plurality of active pixel sensors.

16. The x-ray imaging device of claim 15, wherein the photodetector includes a photodiode layer or a photoconductive material layer.

17. The x-ray imaging device of claim 15, wherein the TFTs form an active pixel sensor circuit that includes a reset TFT, an amplifier TFT, and a readout TFT.

18. The x-ray imaging device of claim 15, wherein the TFTs form a source output current-mode active pixel sensor circuit that includes a reset TFT, an amplifier TFT, and a readout TFT.

19. The x-ray imaging device of claim 15, wherein the TFTs form a drain output current-mode active pixel sensor circuit that includes a reset TFT, an amplifier TFT, and a readout TFT.

20. The x-ray imaging device of claim 15, wherein the TFTs form a source follower voltage-mode active pixel sensor circuit that includes a reset TFT, an amplifier TFT, and a readout TFT.

21. The x-ray imaging device of claim 15, wherein the TFTs form a common source voltage-mode active pixel sensor circuit that includes a reset TFT, an amplifier TFT, and a readout TFT.

22. The x-ray imaging device of claim 15, wherein each of the plurality of active pixel sensors has a pixel pitch of 50 μm.
